(19) United States
(12) Patent Application Publication
(10) Pub. No.: US 2024/0206097 A1
(43) Pub. Date: Jun. 20, 2024

(54) DISPLAY DEVICE

(71) Applicant: AGC Inc., Tokyo (JP)

(72) Inventors: Yasuhiro INOUE, Tokyo (JP); Atsushi INOUE, Tokyo (JP); Toshinari WATANABE, Tokyo (JP); Ryou HOKARI, Tokyo (JP)

(73) Assignee: AGC Inc., Tokyo (JP)

(21) Appl. No.: 18/591,371

(22) Filed: Feb. 29, 2024

Related U.S. Application Data
(63) Continuation of application No. PCT/JP2022/032463, filed on Aug. 29, 2022.

(30) Foreign Application Priority Data
Aug. 30, 2021 (JP) 2021-139604
Apr. 26, 2022 (JP) 2022-072684
Aug. 8, 2022 (JP) 2022-126055

(51) Int. Cl. H05K 5/03

(52) U.S. Cl. CPC H05K 5/03

(57) ABSTRACT

The present invention relates to a display device including: a display panel; a frame including a portion provided outside the display panel; a cover glass including a first main surface and a second main surface, the cover glass being provided on or above the display panel and the frame such that the second main surface faces the display panel and the frame; and a first adhesive layer provided between the second main surface of the cover glass and the frame, the first adhesive layer adhering the second main surface of the cover glass and the frame to each other, in which the first adhesive layer has an elastic modulus of 5 MPa or more and 400 MPa or less in an indentation elastic modulus test.

### CROSS-REFERENCE TO RELATED APPLICATIONS

This is a continuation of International Application No. PCT/JP2022/032463 filed on Aug. 29, 2022, and claims priority from Japanese patent application (Japanese Patent Application No. 2021-139604) filed on Aug. 30, 2021, Japanese patent application (Japanese Patent Application No. 2022-072684) filed on Apr. 26, 2022, and Japanese patent application (Japanese Patent Application No. 2022-126055) filed on Aug. 8, 2022, contents of which are incorporated herein by reference.

### TECHNICAL FIELD

The present invention relates to a display device.

### BACKGROUND ART

A liquid crystal display or an organic electro luminescence (EL) display may be used in an in-vehicle display device or the like that displays information or the like necessary for driving. In such a display, a cover glass may be disposed to protect a front surface. For example, Patent Literature 1 describes a vehicle interior system in which a glass substrate is fixed by a highly elastic adhesive in order to improve crack resistance of the glass substrate.
Patent Literature 1: JP2021-518296A

### SUMMARY OF INVENTION

However, the cover glass tends to have low crack resistance at an edge portion due to latent scratches or the like. Therefore, even when the cover glass cracks from the edge, it is required to prevent floating of fragments of the glass generated when the cover glass cracks. It is also required to prevent display unevenness of a display when the cover glass is attached to the display device.

The present invention has been made in view of the above problems, and an object of the present invention is to provide a display device capable of preventing display unevenness of a display while preventing floating of glass fragments at the time of cracking.

In order to solve the above problems and achieve the object, a display device according to the present disclosure includes: a display panel; a frame including a portion provided outside the display panel; a cover glass including a first main surface and a second main surface, the cover glass being provided on or above the display panel and the frame such that the second main surface faces the display panel and the frame; and a first adhesive layer provided between the second main surface of the cover glass and the frame, the first adhesive layer adhering the second main surface of the cover glass and the frame to each other, in which the first adhesive layer has an elastic modulus of 5 MPa or more and 400 MPa or less in an indentation elastic modulus test.

A display device according to the present invention is capable of preventing display unevenness of a display while preventing floating of glass fragments at the time of cracking.

### BRIEF DESCRIPTION OF DRAWINGS

FIG. 1 is a schematic view illustrating a state in which a display device according to an embodiment is provided in a vehicle.

FIG. 2 is a schematic cross-sectional view illustrating a part of one aspect of the display device according to the present embodiment.

FIG. 3 is a schematic top view illustrating an aspect of a cover glass, a first adhesive layer, and a second adhesive layer in the display device according to the present embodiment.

FIG. 4 is a schematic cross-sectional view illustrating a part of one aspect of the display device according to the present embodiment.

FIG. 5 is a schematic view for explaining a head impact test.

### DESCRIPTION OF EMBODIMENTS

A preferred embodiment of the present invention will be described below in detail with reference to the accompanying drawings. Note that the present invention is not limited to this embodiment and also includes a configuration obtained by combining embodiments when there are a plurality of embodiments. Rounding ranges are included for numerical values.

### (Display Device)

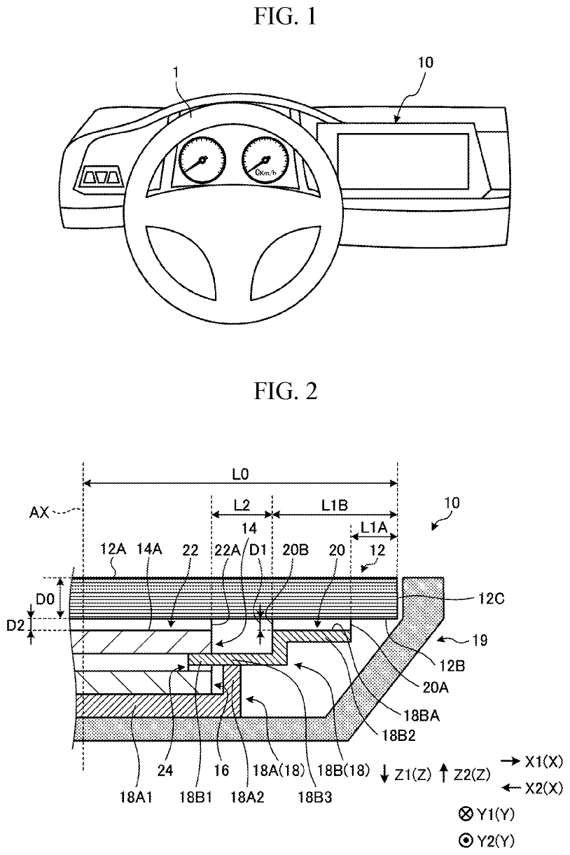

FIG. 1 is a schematic view illustrating a state in which a display device according to an embodiment is provided in a vehicle. As illustrated in FIG. 1, a display device 10 according to the present embodiment is preferably a display device provided in a vehicle, and is provided, for example, in front of a steering shaft 1 inside the vehicle. However, the configuration illustrated in FIG. 1 is an example, and the display device 10 may have any configuration, may be provided at any position, and may be used for any purpose, not limited to vehicle use.

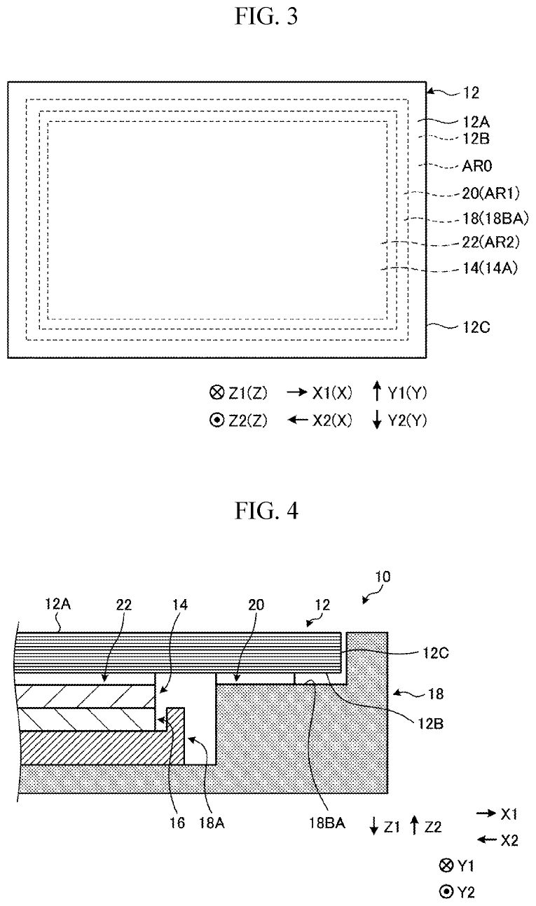

FIG. 2 is a schematic cross-sectional view illustrating a part of the display device. FIG. 2 is a part of a cross-sectional view taken along a line passing through a center and perpendicular to a long side in a top view of FIG. 3.

As illustrated in FIG. 2, the thickness direction of the display device 10, that is, a lamination direction is defined as Z direction, one direction orthogonal to the Z direction, that is, a left-right direction in the example of FIG. 2 is defined as X direction, and a direction orthogonal to the Z direction and the X direction, that is, a direction perpendicular to the paper surface in the example of FIG. 2 is defined as Y direction.

One direction along the X direction, specifically, the right direction in the example of FIG. 2, is defined as direction X1, and the other direction along the X direction, specifically, the left direction in the example of FIG. 2, is defined as direction X2. Similarly, one direction along the Y direction, specifically, a direction toward the back side of the paper surface in the example of FIG. 2 is defined as direction Y1, and the other direction along the Y direction, specifically, a direction toward the front side of the paper surface in the example of FIG. 2 is defined as direction Y2. One direction along the Z direction, specifically, a direction from a display surface toward a back surface of the display device 10 is defined as direction Z1, and the other direction along the Z direction, specifically, a direction from the back surface to the display surface of the display device 10 is defined as direction Z2.

As illustrated in FIG. 2, the display device 10 includes a cover glass 12, a display panel 14, a backlight unit 16, a frame 18, and a housing 19. In the display device 10, the cover glass 12, the display panel 14, and the backlight unit 16 are arranged in order in the direction Z1 in an overlapping manner. The frame 18 is provided surrounding the display panel 14. The frame 18 is a member provided outside the display panel 14 when viewed from the Z direction, in other words, the frame 18 is positioned outside the display panel 14 in a radial direction, that is, on the direction X1 side in the example of FIG. 2. Note that the radial direction here refers to a radial direction when a direction along a central axis AX of the cover glass 12 is defined as an axial direction. The inner side in the radial direction is a direction approaching the central axis AX when viewed from the Z direction, and the outer side in the radial direction is a direction away from the central axis AX when viewed from the Z direction. The same applies hereinafter unless otherwise specified. Note that the central axis AX is an axis along the Z direction, passing through a center position of the cover glass 12 when viewed from the Z direction. The central axis AX can also be referred to as an axis passing through a center in the top view and parallel to the Z direction. For example, a center of gravity in the top view is used as the center, and when the center of gravity is positioned outside the cover glass 12, a method in which coordinate data of the outline of the cover glass 12 is acquired to obtain a coordinate center is used.

A first adhesive layer 20 is provided between the cover glass 12 and the frame 18 in the Z direction, and the cover glass 12 and the frame 18 are adhered to each other by the first adhesive layer 20 and thus fixed to each other. A second adhesive layer 22 is preferably provided between the cover glass 12 and the display panel 14 in the Z direction, and it is preferable that the cover glass 12 and the display panel 14 are adhered to each other by the second adhesive layer 22 and thus fixed to each other.

The housing 19 is a case that houses the cover glass 12, the display panel 14, the backlight unit 16, the frame 18, the first adhesive layer 20, and the second adhesive layer 22. Note that the housing 19 is not an essential component.

### (Cover Glass)

The cover glass 12 is a transparent plate-shaped member that transmits visible light. The cover glass 12 includes a first main surface 12A which is a main surface on the direction Z2 side, that is, on the display surface side, a second main surface 12B which is a main surface on the direction Z1 side, that is, on the back surface side, and an end surface 12C connecting the first main surface 12A and the second main surface 12B. The end surface 12C is an end surface on an outer side in the radial direction of the cover glass 12 and can also be referred to as a side surface of the cover glass 12.

The thickness D0 of the cover glass 12 is preferably 0.3 mm or more and 2.5 mm or less. As for a lower limit, the thickness D0 is preferably 0.3 mm or more, more preferably 0.4 mm or more, and still more preferably 0.6 mm or more. As for an upper limit, the thickness D0 of the cover glass 12 is preferably 2.5 mm or less, more preferably 2.0 mm or less, and still more preferably 1.3 mm or less. That is, in the case where the lower limit of the thickness D0 is the above value, it is possible to ensure rigidity of the cover glass 12 and prevent cracking, and in the case where the upper limit of the thickness D0 is the above value, it is possible to easily prevent peeling of the cover glass 12 from the frame 18. Especially, in the case of a cold-formed product described below, it is preferable that the thickness D0 is 1.3 mm or less so that the product is easily curved. Note that the thickness D0 is the length from the first main surface 12A to the second main surface 12B in the Z direction.

In the example of the present embodiment, the cover glass 12 has a flat plate shape that is rectangular when viewed from the Z direction. As for the size of the cover glass 12, for example, in the case where the cover glass 12 is rectangular, the length in the longitudinal direction, that is, the length in the X direction in the example of the present embodiment, is 100 mm or more and 800 mm or less, and the length in the short direction, that is, the length in the Y direction in the example of the present embodiment is 40 mm or more and 300 mm or less. However, the cover glass 12 is not limited to a flat plate shape having a rectangular shape when viewed from the Z direction, and may have any shape, and for example, it may have an elliptical shape when viewed from the Z direction, or may have a curved shape for example. The size of the cover glass 12 may also be freely set.

In the case where the cover glass 12 has a curved shape, the thickness direction of the cover glass 12 at a center position of a main surface of the cover glass 12 may be defined as the Z direction. That is, a direction perpendicular to the main surface of the cover glass 12 at the center position of the main surface of the cover glass 12 may be defined as the Z direction.

Note that a method for forming the curved shape is not particularly limited, and for example, the curved shape may be formed by a heat forming method or a cold forming method. The cold forming method refers to a method of bending a glass into a desired shape without increasing the temperature of the glass to a softening point. In the case of the cold forming method, the cover glass 12 is attached to the frame 18 by bending a glass plate in a flat plate shape by the cold forming method. In the cold forming method, since a relatively thin glass is preferably used, fragments are likely to be generated due to impact, but by using the cover glass 12 of the present embodiment, floating of fragments can be significantly reduced.

The Young's modulus of the cover glass 12 is preferably 60 GPa or more, and more preferably 70 GPa or more. The Young's modulus of the cover glass 12 is preferably 90 GPa or less, more preferably 80 GPa or less, and still more preferably 75 GPa or less. That is, the Young's modulus of the cover glass 12 is preferably 60 GPa or more and 90 GPa or less, more preferably 70 GPa or more and 80 GPa or less, and still more preferably 70 GPa or more and 75 GPa or less. In the case where the Young's modulus falls within this range, cracking can be prevented. The Young's modulus of each member, including the cover glass 12, may be obtained by a tensile test in accordance with JIS K7161 (2014).

The cover glass 12 is made of glass. The cover glass 12 is preferably a strengthened glass, and the strengthened glass is preferably a chemically strengthened glass.

In the case where the cover glass 12 is a chemically strengthened glass, the depth of compressive stress layer (DOL) of the cover glass 12 is, for example, preferably 10 μm or more, more preferably 15 μm or more, still more preferably 25 μm or more, and even more preferably 30 μm or more. The depth of compressive stress layer (DOL) is, for example, preferably 180 μm or less, and more preferably 50 μm or less. Regarding the depth of compressive stress layer (DOL), preferably at least one of the first main surface 12A and the second main surface 12B of the cover glass 12 falls within the above range, and more preferably both fall within the above range.

The surface compressive stress (CS) in the compressive stress layer is preferably 500 MPa or more, more preferably 650 MPa or more, and still more preferably 750 MPa or more. An upper limit is not particularly limited, but for example, CS is preferably 1200 MPa or less. Regarding the surface compressive stress, preferably at least one of the first main surface 12A and the second main surface 12B of the cover glass 12 falls within the above range, and more preferably both fall within the above range.

In the case where DOL or CS falls within the respective range, cracking can be prevented.

Examples of a method for subjecting glass to a chemical strengthening treatment to obtain a chemically strengthened glass include, typically, a method of immersing glass in a KNO₃ molten salt to conduct an ion exchange treatment, followed by cooling the glass to around room temperature. Treatment conditions such as a temperature of the KNO₃ molten salt and an immersion time may be set such that the surface compressive stress and the depth of the compressive stress layer become desired values.

Examples of the glass type include soda-lime glass and aluminosilicate glass (SiO₂—Al₂O₃—Na₂O-based glass). Among these, aluminosilicate glass is preferred from the viewpoint of strength.

Examples of the glass material include a glass material containing, in terms of mol % based on oxides, 50% or more and 80% or less of SiO₂, 1% or more and 20% or less of Al₂O₃, 6% or more and 20% or less of Na₂O, 0% or more and 11% or less of K₂O, 0% or more and 15% or less of MgO, 0% or more and 6% or less of CaO, and 0% or more and 5% or less of ZrO₂.

A glass for chemical strengthening based on an aluminosilicate glass is also preferably used, and examples thereof include “Dragon Trail (registered trademark)” manufactured by AGC Inc.

More specifically, examples of a more preferable composition of the glass for the cover glass 12 include the following glass composition. Note that for example, “containing 0% to 25% of MgO” means that MgO is not essential but may be contained up to 25%. The glass of (i) below is categorized in soda-lime silicate glass, the glasses of (ii) and (iii) below are categorized in aluminosilicate glass, and the glasses of (iv) to (vi) below are categorized in lithium aluminosilicate glass.
(i) A glass having a composition containing, in terms of mol % based on oxides, 63% to 73% of SiO₂, 0.1% to 5.2% of Al₂O₃, 10% to 16% of Na₂O, 0% to 1.5% of K₂O, 0% to 5.0% of Li₂O, 5% to 18% of MgO, and 1% to 10% of CaO.
(ii) A glass having a composition containing, in terms of mol % based on oxides, 50% to 74% of SiO₂, 5% to 15% of Al₂O₃, 10% to 20% of Na₂O, 0% to 8% of K₂O, 0% to 5.0% of Li₂O, 2% to 15% of MgO, 0% to 6% of CaO, and 0% to 5% of ZrO₂, in which the total content of SiO₂ and Al₂O₃ is 65% to 85%, the total content of Na₂O and K₂O is 12% to 25%, and the total content of MgO and CaO is 1% to 15%.
(iii) A glass having a composition containing, in terms of mol % based on oxides, 68% to 80% of SiO₂, 4% to 10% of Al₂O₃, 5% to 15% of Na₂O, 0% to 1% of K₂O, 0% to 5.0% of Li₂O, 4% to 15% of MgO, and 0% to 1% of ZrO₂.
(iv) A glass having a composition containing, in terms of mol % based on oxides, 67% to 75% of SiO₂, 0% to 4% of Al₂O₃, 7% to 15% of Na₂O, 1% to 9% of K₂O, 0% to 5.0% of Li₂O, 6% to 14% of MgO, and 0% to 1.5% of ZrO₂, in which the total content of SiO₂ and Al₂O₃ is 71% to 75%, the total content of Na₂O and K₂O is 12% to 20%, and the content of CaO is less than 1% in the case where CaO is contained.
(v) A glass having a composition containing, in terms of mol % based on oxides, 50% to 73% of SiO₂, 5% to 20% of Al₂O₃, 0% to 6% of B₂O₃, 0% to 10% of P₂O₅, 4% to 12% of Li₂O, 3% to 20% of Na₂O, 0% to 5% of K₂O, 0% to 8% of MgO, 0% to 2% of CaO, 0% to 5% of SrO, 0% to 5% of BaO, 0% to 5% of ZnO, 0% to 2% of TiO₂, and 0% to 4% of ZrO₂.
(vi) A glass having a composition containing, in terms of mol % based on oxides, 58% to 80% of SiO₂, 13% to 18% of Al₂O₃, 0% to 5% of B₂O₃, 0.5% to 4% of P₂O₅, 3% to 10% of Li₂O, 5% to 20% of Na₂O, 0% to 2% of K₂O, 0% to 11% of MgO, 0% to 20% of CaO, 0% to 20% of SrO, 0% to 15% of BaO, 0% to 10% of ZnO, 0% to 1% of TiO₂, and 0% to 2% of ZrO₂.

The tensile stress of the cover glass 12 is preferably 5 MPa or more, more preferably 5 MPa or more and 100 MPa or less, still more preferably 8 MPa or more and 80 MPa or less, or 5 MPa or more and 70 MPa or less, and even more preferably 8 MPa or more and 70 MPa or less.

In the case where the tensile stress falls within this range, cracking can be prevented. Note that the tensile stress of the cover glass 12 refers to an internal tensile stress CT of the cover glass 12.

### (Display Panel)

The display panel 14 is a panel that displays an image, and is disposed on the direction Z1 side of the cover glass 12 in a manner of overlapping the cover glass 12. A display surface of the display panel 14, which is a surface on the direction Z2 side, may be adhered to the second main surface 12B of the cover glass 12 by the second adhesive layer 22.

The display panel 14 is a liquid crystal panel, an organic EL panel, a flexible organic EL panel, a plasma display (PDP), an electronic ink panel, or the like, and may include a touch panel or the like. In the case where the display panel 14 includes a glass substrate, the glass substrate is the thickest and controls rigidity of the entire display panel. Therefore, the Young's modulus of the glass substrate may be regarded as the Young's modulus of the display panel 14.

The Young's modulus of the display panel 14 is preferably 2 GPa or more, more preferably 60 GPa or more, and still more preferably 70 GPa or more. The Young's modulus of the display panel 14 is preferably 90 GPa or less, and more preferably 75 GPa or less. That is, the Young's modulus of the display panel 14 is preferably 20 GPa or more and 90 GPa or less, more preferably 60 GPa or more and 75 GPa or less, and still more preferably 70 GPa or more and 75 GPa or less.

The thickness of the display panel 14 is preferably 0.05 mm or more, more preferably 1.0 mm or more, and still more preferably 1.1 mm or more. The thickness of the display panel is preferably 2.0 mm or less, and more preferably 1.3 mm or less. That is, the thickness of the display panel 14 is preferably 0.05 mm or more and 2.0 mm or less, more preferably 1.0 mm or more and 1.3 mm or less, and still more preferably 1.1 mm or more and 1.3 mm or less. Note that the thickness of the display panel 14 is the length in the Z direction from the main surface on the direction Z1 side to the main surface on the direction Z2 side of the display panel 14.

### (Backlight Unit)

The backlight unit 16 is a light source that irradiates the display panel 14 with light for image display, and is disposed on the direction Z1 side of the display panel 14 in a manner of overlapping the display panel 14.

The backlight unit 16 is generally composed of members such as a lens sheet, a diffusion sheet, a light guide plate, a lamp, and a reflector. Among these members, in general, the light guide plate is the thickest and the light guide plate controls rigidity of the entire backlight unit 16. Therefore, the Young's modulus of the light guide plate may be regarded as the Young's modulus of the backlight unit 16.

The Young's modulus of the backlight unit 16 is preferably 1 GPa or more and 5 GPa or less, and more preferably 2 GPa or more and 5 GPa or less.

The thickness of the backlight unit 16 is preferably 1 mm or more, more preferably 2 mm or more, and still more preferably 3 mm or more. The thickness of the backlight unit 16 is preferably 10 mm or less, more preferably 6 mm or less, and still more preferably 5 mm or less. That is, the thickness of the backlight unit 16 is preferably 1 mm or more and 10 mm or less, more preferably 2 mm or more and 6 mm or less, and still more preferably 3 mm or more and 5 mm or less. Note that the thickness of the backlight unit 16 is the length in the Z direction from a main surface on the direction Z1 side to a main surface on the direction Z2 side of the backlight unit 16.

Note that the display device 10 may not be provided with the backlight unit 16. In the case where the backlight unit 16 is not provided, a self-luminous display panel that does not require the backlight unit 16, such as an organic EL panel or a micro LED panel, is selected as the display panel 14.

### (Frame)

The frame 18 is a member including a portion provided outside the display panel 14 when viewed from the Z direction. That is, the frame 18 is a member that at least a part thereof is provided outside the display panel 14 when viewed from the Z direction. The Young's modulus of the frame 18 is preferably 1.5 GPa or more and 250 GPa or less, more preferably 10 GPa or more and 230 GPa or less, and even more preferably 60 GPa or more and 230 GPa or less.

A material of the frame 18 is freely selected, and for example, a single-component metal containing a metal element such as aluminum or magnesium, or an alloy thereof is preferable. The material of the frame 18 may be a resin or a laminate of a resin layer and a metal layer.

In the example of FIG. 2, a bottom member 18A and a side wall member 18B are provided as the frame 18, and the bottom member 18A is provided on the direction Z1 side of the display panel 14, and the side wall member 18B is provided on an outer side in the radial direction of the display panel 14. That is, in the example of FIG. 2, the side wall member 18B includes a portion provided outside the display panel 14 when viewed from the Z direction.

In the example of FIG. 2, the bottom member 18A has a plate-shaped bottom portion 18A1 and a frame-shaped frame portion 18A2 protruding from a periphery of the bottom portion 18A1 toward the direction Z2. The bottom member 18A houses the backlight unit 16 by disposing the backlight unit 16 in a space formed by the bottom portion 18A1 and the frame portion 18A2.

In the example of FIG. 2, the side wall member 18B is a frame-shaped member surrounding the display panel 14, and is supported by the frame portion 18A2 at a position 18B3 between a position 18B1 and a position 18B2. Note that the position 18B1 is a position on an inner side in the radial direction of the side wall member 18B, that is, a position on the direction X2 side in the example of FIG. 2, and the position 18B2 is a position on an outer side in the radial direction of the side wall member 18B, that is, a position on the direction X1 side in the example of FIG. 2. In the example of FIG. 2, the position 18B1 of the side wall member 18B is disposed between the display panel 14 and the backlight unit 16 in the Z direction, and is adhered to the surface of the backlight unit 16 on the direction Z2 side by an adhesive layer 24. In the example of FIG. 2, the frame 18 is fixed to the second main surface 12B side of the cover glass 12 via the first adhesive layer 20 at the position 18B2 of the side wall member 18B.

However, the shape of the frame 18 is not limited to the example of FIG. 2, and may be freely set. The frame 18 may be any member that includes a portion provided outside the display panel 14 when viewed in the Z direction, in which the portion provided outside the display panel 14 is adhered to the second main surface 12B side of the cover glass 12 via the first adhesive layer 20. For example, as illustrated in FIG. 4, which will be described later, a housing that houses the cover glass 12, the display panel 14, and the backlight unit 16 may be regarded as the frame 18.

In FIG. 2, for example, the frame 18 may not include the bottom member 18A, and may include only the frame-shaped side wall member 18B.

### (First Adhesive Layer)

FIG. 3 is a schematic top view illustrating one aspect of the cover glass, the first adhesive layer, and the second adhesive layer in the display device. As illustrated in FIG. 2, the first adhesive layer 20 is a layer of an adhesive that is provided between the cover glass 12 and the frame 18 in the Z direction and adheres the cover glass 12 to the frame 18. The first adhesive layer 20 adheres a surface 18BA of the frame 18 on the direction Z2 side to the second main surface 12B of the cover glass 12. As illustrated in FIG. 2 and FIG. 3, in the example of the present embodiment, since the surface 18BA of the frame 18 is provided in a manner of surrounding the periphery of the display panel 14, the first adhesive layer 20 is also provided in a manner of surrounding the periphery of the display panel 14.

The elastic modulus of the first adhesive layer 20 in an indentation elastic modulus test is 5 MPa or more and 400 MPa or less, preferably 8 MPa or more and 400 MPa or less, more preferably 10 MPa or more and 400 MPa or less, still more preferably 12 MPa or more and 350 MPa or less, even more preferably 15 MPa or more and 300 MPa or less, and particularly preferably 100 MPa or more and 300 MPa or less. Here, a lower limit of the elastic modulus is 5 MPa, preferably 8 MPa or more, more preferably 10 MPa or more, still more preferably 12 MPa or more, even more preferably 15 MPa or more, and particularly preferably 100 MPa or more. An upper limit of the elastic modulus is 400 MPa, preferably 350 MPa or less, and more preferably 300 MPa or less. In the case where the elastic modulus is 5 MPa or more, strength against peeling can be sufficiently maintained, and glass fragments can be prevented from floating when an edge of the cover glass 12 cracks. In the case where the elastic modulus is 400 MPa or less, display unevenness of the display can be prevented.

Note that the indentation elastic modulus test in the present embodiment is performed by the following method.

The first adhesive layer 20 adhered to the second main surface 12B of the cover glass 12 and the frame is exposed toward an upper side in a vertical direction, and is disposed in a creep meter (for example, model number RE2-33005C, manufactured by Yamaden Co., Ltd.), and a plunger (a cylindrical plunger, model number P-61, diameter 1.5 mm, height 40 mm, manufactured by Yamaden Co., Ltd.) is indented into the first adhesive layer 20 at an indentation speed of 0.05 mm/sec in an environment of room temperature, for example, 20° C. and 50% relative humidity, and then a load acting on the plunger when indented in and an amount of displacement of the plunger in an indentation direction are sequentially measured. The measured load and amount of displacement are plotted every time, and a slope of an approximate line of each plotted point in a section where the indentation depth is from 5% to 10% of the thickness of the first adhesive layer 20 is calculated as the elastic modulus of the first adhesive layer 20.

A method for exposing the first adhesive layer 20 is not particularly limited, but a method in which the adhesive is not denatured is preferable. For example, there is a method in which a metal thin plate or the like is inserted between the first adhesive layer 20 and the cover glass 12 or the frame 18, which is an object to be adhered, and the first adhesive layer 20 is physically peeled off. In the case where the first adhesive layer 20 is broken in the middle of the thickness direction during peeling, it is preferable to measure the elastic modulus on the adhesive layer which remains thicker.

It is also preferable to measure the elastic modulus using the adhesive layer remaining on a side where the Young's modulus is higher in the frame and the cover glass. That is, in the case where the frame is made of metal, the adhesive layer is preferably left on the frame side, and in the case where the frame is made of resin having a low Young's modulus, the adhesive layer is preferably left on the cover glass side, to measure the elastic modulus.

Here, the meaning of the indentation elastic modulus test in the present embodiment will be described. In a glass article, an adhesive adheres a glass surface of a cover glass or a printed surface on the glass surface to a frame made of metal or resin, but it is generally designed that the peeling occurs by breaking the adhesive when an attempt is made to peel the adhered glass surface off from the frame to be adhered. It is known that adhesive strength when the adhesive is broken depends on tensile elastic modulus of the adhesive. However, a cross-type adhesive strength test, an H-type adhesive strength test, or the like, which are known as existing adhesive strength tests, is difficult to perform measurement in a glass article in a state where a cover glass and a frame are adhered to each other. In the present embodiment, as an evaluation method instead of the existing adhesive strength test, the indentation elastic modulus test capable of verifying from a glass article in a state where a cover glass and a frame are adhered to each other was adopted. In the present embodiment, since it is known that the adhesive is broken when the glass article and the frame are peeled off, and that there is generally a positive correlation between the tensile elastic modulus and the indentation elastic modulus, it is presumed that there is also a correlation between the adhesive strength and the elastic modulus in the indentation test.

The thickness D1 of the first adhesive layer 20 is preferably 0.2 mm or more and 4.0 mm or less, more preferably 0.5 mm or more and 3.5 mm or less, and still more preferably 1.0 mm or more and 3.0 mm or less. Here, a lower limit of the thickness D1 of the first adhesive layer 20 is preferably 0.2 mm, more preferably 0.5 mm or more, and still more preferably 1.0 mm or more. An upper limit of the thickness D1 is preferably 4.0 mm, more preferably 3.5 mm or less, and still more preferably 3.0 mm or less. In the case where the thickness D1 is in this range, the elastic modulus can be in an appropriate range, and the display unevenness of the display can be preferably prevented while preferably reducing the floating of the glass fragments when the cover glass cracks. Note that the thickness D1 is the length in the Z direction from the surface on the direction Z1 side to the surface on the direction Z2 side of the first adhesive layer 20.

FIG. 3 is a schematic top view illustrating the second main surface of the cover glass 12 when viewed from the Z direction. The area of the second main surface 12B of the cover glass 12 is defined as an area AR0, and the area of the first adhesive layer 20 is defined as an area AR1. In this case, the ratio of the area AR1 of the first adhesive layer 20 to the area AR0 of the second main surface 12B is preferably 5% or more and 65% or less, more preferably 8% or more and 50% or less, and still more preferably 10% or more and 40% or less. Here, a lower limit of the area ratio is preferably 5%, more preferably 8% or more, and still more preferably 10% or more. An upper limit of the ratio is preferably 65%, more preferably 50% or less, and still more preferably 40% or less. In the case where the ratio of the area AR1 of the first adhesive layer 20 is within this range, cracking of the cover glass 12 can be preferably prevented.

As illustrated in FIG. 2, the minimum distance in the radial direction from the central axis AX of the cover glass 12 to the end surface 12C, that is, the distance in the X direction in the example of FIG. 2 is defined as a distance LO. The minimum distance in the radial direction from the end surface 12C of the cover glass 12 to an outer end 20A of the first adhesive layer 20, that is, the distance in the X direction in the example of FIG. 2 is defined as a distance L1A. The end 20A is an end portion on the outer side in the radial direction of the first adhesive layer 20, that is, on the direction X1 side in the example of FIG. 2. The minimum distance in the radial direction from the end surface 12C of the cover glass 12 to an inner end 20B of the first adhesive layer 20, that is, the distance in the X direction in the example of FIG. 2 is defined as a distance L1B. The end 20B is an end on the inner side in the radial direction of the first adhesive layer 20, that is, on the direction X2 side in the example of FIG. 2.

In this case, the ratio of the distance L1A to the distance LO is preferably 0% or more and 10% or less, more preferably 0.3% or more and 8% or less, and still more preferably 0.5% or more and 5% or less. The distance L1A is preferably 0 mm or more and 10 mm or less, more preferably 0.1 mm or more and 8 mm or less, and still more preferably 0.2 mm or more and 5 mm or less. Here, a lower limit of the distance L1A is 0 mm, preferably 0.1 mm or more, and more preferably 0.2 mm or more. An upper limit of the distance L1A is preferably 10 mm or less, more preferably 8 mm or less, and still more preferably 5 mm or less.

The ratio of the distance L1B to the distance LO is preferably 0.1% or more and 50% or less, more preferably 1% or more and 40% or less, and still more preferably 2% or more and 10% or less. The distance L1B is preferably 0.5 mm or more and 60 mm or less, more preferably 1 mm or more and 30 mm or less, and still more preferably 3 mm or more and 10 mm or less. Here, a lower limit of the distance L1B is preferably 0.5 mm or more, more preferably 1 mm or more, and still more preferably 3 mm or more. An upper limit of the distance L1B is preferably 60 mm or less, more preferably 30 mm or less, and still more preferably 10 mm or less.

In the case where the distance L1A or the distance L1B falls within the respective range, it is possible to appropriately adhere the vicinity of the edge of the cover glass 12, and it is possible to preferably prevent the floating of the fragments when the edge of the cover glass 12 cracks.

The first adhesive layer 20 may be any adhesive, and examples of the material of the first adhesive layer 20 include epoxy resin, urethane resin, and acrylic resin.

### (Second Adhesive Layer)

As illustrated in FIG. 2, the second adhesive layer 22 is a layer of an adhesive that is provided between the cover glass 12 and the display panel 14 in the Z direction and adheres the cover glass 12 to the display panel 14. The second adhesive layer 22 bonds the display surface, which is the surface 14A on the direction Z2 side of the display panel 14, to the second main surface 12B of the cover glass 12. The second adhesive layer 22 is preferably positioned on the inner side in the radial direction than the first adhesive layer 20 and away from the first adhesive layer 20. Note that in the example of FIG. 3, the second adhesive layer 22 is provided over the entire area of the display panel 14, but it is not limited thereto, and may be provided only on a part of the display panel 14 or may be provided on a wider area than the display panel 14.

The elastic modulus of the second adhesive layer 22 in an indentation elastic modulus test is preferably lower than the elastic modulus of the first adhesive layer 20. The elastic modulus of the second adhesive layer 22 in the indentation elastic modulus test is preferably 0.5 MPa or more and 100 MPa or less, more preferably 1 MPa or more and 80 MPa or less, and still more preferably 2 MPa or more and 50 MPa or less. In the case where the elastic modulus falls within this range, the display panel 14 and the cover glass 12 can be appropriately adhered to each other, and display unevenness of the display can be prevented. Note that the indentation elastic modulus test for the second adhesive layer 22 is also performed by the same method as that for the first adhesive layer 20.

The thickness D2 of the second adhesive layer 22 is preferably 0.05 mm or more and 4.0 mm or less, more preferably 0.1 mm or more and 3.5 mm or less, and still more preferably 0.2 mm or more and 3 mm or less. In the case where the thickness D2 falls within this range, the elastic modulus can be in an appropriate range, and the display unevenness of the display can be prevented while appropriately adhering the display panel 14 to the cover glass 12. Note that the thickness D2 is the length in the Z direction from the surface on the direction Z1 side to the surface on the direction Z2 side of the second adhesive layer 22.

As illustrated in FIG. 3, the area of the second adhesive layer 22 when viewed from the Z direction is defined as an area AR2. In this case, the ratio of the area AR2 of the second adhesive layer 22 to the area AR0 of the second main surface 12B of the cover glass 12 is preferably 30% or more and 90% or less, more preferably 40% or more and 85% or less, and still more preferably 50% or more and 80% or less. In the case where the area AR2 of the second adhesive layer 22 falls within this range, the display panel 14 and the cover glass 12 can be appropriately adhered to each other.

As illustrated in FIG. 2, the distance in the radial direction from the inner end 20B of the first adhesive layer 20 to an outer end 22A of the second adhesive layer 22, that is, the distance in the X direction in the example of FIG. 2, is defined as a distance L2. The end 22A is an end on the outer side in the radial direction of the second adhesive layer 22, that is, on the direction X1 side in the example of FIG. 2.

In this case, the ratio of the distance L2 to the distance LO is preferably 0.5% or more and 15% or less, more preferably 1% or more and 12% or less, and still more preferably 2% or more and 10% or less. The distance L2 is preferably 0.1 mm or more and 10 mm or less, more preferably 0.3 mm or more and 8 mm or less, and still more preferably 0.5 mm or more and 5 mm or less.

The second adhesive layer 22 is preferably an adhesive having a composition different from that of the first adhesive layer 20. The second adhesive layer 22 may be, for example, acrylic resin or silicone resin. In the case where the second adhesive layer 22 and the first adhesive layer 20 are different from each other, it is easy to prevent cracking from the end of the cover glass 12 while preventing display unevenness of the display.

### (Other Configuration Examples)

FIG. 4 is a schematic cross-sectional view illustrating a part of another aspect of the display device according to the present embodiment. In the example illustrated in FIG. 2, the frame 18 and the cover glass 12, which are housed in the housing 19, are adhered to each other by the first adhesive layer 20. However, the present invention is not limited thereto, and as illustrated in FIG. 4, a housing that houses the cover glass 12 and the display panel 14 may be regarded as the frame 18. That is, the frame 18, which is a housing that houses the cover glass 12 and the display panel 14, and the cover glass 12 may be adhered to each other via the first adhesive layer 20.

### (Effects)

As described above, in the display device 10 according to the present embodiment, the elastic modulus of the first adhesive layer 20 that adheres the cover glass 12 to the frame 18 is 5 MPa or more and 400 MPa or less. Accordingly, display unevenness of the display can be prevented while reducing the floating of glass fragments when the edge (periphery) of the cover glass 12 cracks.

### (Head Impact Test)

Whether the glass fragments float when the edge of the cover glass 12 cracks can be evaluated by a head impact test. Hereinafter, the head impact test will be described.

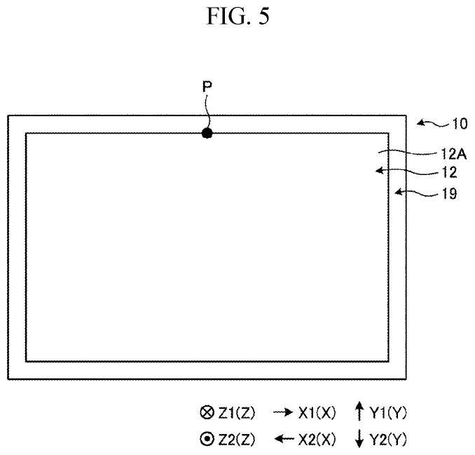

FIG. 5 is a schematic view for explaining a head impact test. As illustrated in FIG. 5, when the head impact test is performed, the display device 10 is displaced on a horizontal surface such that the first main surface 12A of the cover glass 12 faces upward in the vertical direction. Then, a spherical rigid model (material: iron, diameter: 165 mm, mass: 19.6 kg) (not illustrated) is dropped from a height of 793 mm at a collision speed of 3.944 m/s to collide with a collision position P of the first main surface 12A of the cover glass 12 so that energy at collision becomes 152.4 J.

The test method may refer to the “Attachment 28: technical standard of impact absorption of instrument panel” (hereinafter, simply referred to as “standard”) of the “Article 20: vehicle” of the “safety standard of road transportation vehicle” indicated by the Ministry of Land, Infrastructure, Transport and Tourism. In the “standard”, a spherical rigid model (material: iron, diameter: 165 mm, mass: 6.8 kg) is ejected at a collision speed of 6.7 m/s to collide so as to obtain energy at collision of 152.4 J. That is, in the head impact test, it is preferable that the energy at collision is equal to that in the “standard”.

The collision position P on the cover glass 12 with which the rigid model collides is on the first main surface 12A of the cover glass 12, is a center position of the first main surface 12A in the X direction, and is a position 1 mm away from the end surface 12C on the direction Y1 side of the cover glass 12 toward the direction Y2 side in the Y direction.

The head impact test is performed under the above conditions, and a floating degree of the fragments of the cover glass 12 when the edge (near the collision position P) of the cover glass 12 cracks can be evaluated by, for example, observing a distance in the Z direction from a non-cracking position of the first main surface 12A to a tip of the fragments.

### (Display Unevenness of Display)

Since the second main surface 12B of the cover glass 12 and the surface 18BA of the frame 18 do not have a strictly flat shape, when the second main surface 12B and the surface 18BA are brought into contact with each other, a gap amount varies from position to position. In the case where there is a variation in the gap amount in this manner, a variation also occurs in a manner in which light passes and emitted through the cover glass 12 from the display panel 14, for example, from the backlight unit 16 in the present embodiment, and thus, for example, shading occurs in luminance, and display unevenness occurs. In this regard, in the present embodiment, the relatively soft first adhesive layer 20 having an elastic modulus of 400 MPa or less is provided between the second main surface 12B and the surface 18BA, and thus this variation in gap amount is absorbed, and display unevenness can be prevented. On the other hand, for example, in the case where the first adhesive layer 20 does not satisfy the condition of the elastic modulus of 400 MPa or less and is hardened, the variation in the gap amount cannot be absorbed, and the display unevenness cannot be prevented.

The present disclosure describes the following invention. Note that the present invention is not limited thereto.
(1) A display device, including: a display panel 14; a frame 18 including a portion provided outside the display panel 14; a cover glass 12 including a first main surface 12A and a second main surface 12B, the cover glass being provided on or above the display panel 14 and the frame 18 such that the second main surface 12B faces the display panel 14 and the frame 18; and a first adhesive layer 20 provided between the second main surface 12B of the cover glass 12 and the frame 18, the first adhesive layer adhering the second main surface 12B of the cover glass 12 and the frame 18 to each other, in which the first adhesive layer 20 has an elastic modulus of 5 MPa or more and 400 MPa or less in an indentation elastic modulus test.
(2) The display device according to (1), in which the cover glass 12 is a chemically strengthened glass having a depth of compressive stress layer being 10 μm or more, has a thickness D0 of 0.3 mm or more and 2.5 mm or less, and has a tensile stress of 5 MPa or more.
(3) The display device according to (1) or (2), in which the first adhesive layer 20 has a thickness D1 of 0.2 mm or more and 4.0 mm or less.
(4) The display device according to any one of (1) to (3), having a ratio of an area AR1 of the first adhesive layer 20 to an area AR0 of the second main surface 12B of the cover glass 12 being 5% or more and 65% or less.
(5) The display device according to any one of (1) to (4), having a distance LIA from an end surface 12C of the cover glass 12 to an end 20A on an outer side of the first adhesive layer 20 being 0 mm or more and 10 mm or less.
(6) The display device according to (5), having a distance L1B from the end surface 12C of the cover glass 12 to an end 20B on an inner side of the first adhesive layer 20 being 0.5 mm or more and 60 mm or less.
(7) The display device according to any one of (1) to (6), further including: a second adhesive layer 22 provided between the second main surface 12B of the cover glass 12 and the display panel 14, the second adhesive layer adhering the second main surface 12B of the cover glass 12 and the display panel 14 to each other, in which the second adhesive layer 22 is formed of an adhesive having a composition different from that of the first adhesive layer 20.
(8) The display device according to (7), in which the second adhesive layer 22 has an elastic modulus in the indentation elastic modulus test being lower than the elastic modulus of the first adhesive layer 20 in the indentation elastic modulus test.

### EXAMPLES

Next, Examples will be described. Table 1 is a table showing samples of respective Examples relating to adhesives to be the adhesive layer. Examples 1 and 2 are Comparative Examples, and Examples 3 to 6 are Inventive Examples.

Note that Examples 1 to 6 are examples relating to the adhesive layer, and are not examples in which the adhesive layer is provided between a cover glass and a frame to adhere the two, and are not display devices including the first adhesive layer. However, in the case where the adhesive is applied onto a main surface of the cover glass and cured to form an adhesive layer, it is possible to predict, based on the elastic modulus thereof, results relating to the floating of glass fragments when the edge of the cover glass cracks and the display unevenness of the display in the case where it is used as the first adhesive layer of the display device, and thus it is treated as an Example or Comparative Example.

TABLE 1

| | Example 1 | Example 2 | Example 3 | Example 4 | Example 5 | Example 6 |
|---|---|---|---|---|---|---|
| Material | Epoxy | Acrylic | Urethane | Epoxy | Epoxy | Epoxy |
| Curing type | Two- | — | One- | One- | One- | One- |
| | component | (Tape type) | component | component | component | component |
| | | | heating type | heating type | heating type | heating type |
| Maker | Masterbond | 3M | ThreeBond | ThreeBond | ThreeBond | ThreeBond |
| Model | EP21 | VHX1701 | 1539 | 2235L | 2235L | 2206S |
| number | TDCHT-LO | | | | | |
| Thickness | 2 | 1 | 1 | 0.4 | 1 | 2 |
| (mm) | | | | | | |
| Elastic | 500 | 1 | 15 | 34 | 142 | 250 |
| modulus | | | | | | |
| (MPa) | | | | | | |
| Fragment | A | C | B | B | A | A |
| floating | | | | | | |
| Display | C | B | B | B | B | B |
| unevenness | | | | | | |

### Example 1

In Example 1, a two-component curing type epoxy resin adhesive (EP21TDCHT-LO, manufactured by Masterbond Company) was applied to a main surface of a cover glass so as to have a thickness of 2 mm, and the adhesive was cured by heating in a curing condition of 200° C. for 180 minutes to form an adhesive layer. When an indentation elastic modulus test was performed by the method described in the present embodiment and the elastic modulus of the formed adhesive layer was calculated, the elastic modulus of the adhesive layer in Example 1 was 500 MPa.

### Examples 2 to 6

In Examples 2 to 6, the adhesive layer was formed in the same manner as in Example 1 except that the material of the adhesive, the thickness of the adhesive layer, and the curing condition were changed as shown in Table 1. The indentation elastic modulus of the adhesive layer of each Example was the respective value shown in Table 1.

In Examples 3 to 6, which are Inventive Examples, since the elastic modulus of the adhesive layer was 5 MPa or more and 400 MPa or less, the display unevenness of the display can be prevented while reducing the floating of the glass fragments when the edge of the cover glass cracks. Especially, in Examples 5 and 6, in which the elastic modulus is 100 MPa or more, the floating of the fragments can be reduced more satisfactorily.

On the other hand, in Example 1 as a Comparative Example, since the elastic modulus of the adhesive is too high as 500 MPa, the variation in the gap amount cannot be absorbed, and the display unevenness when the display is provided cannot be prevented. In Example 2 as a Comparative Example, since the elastic modulus of the adhesive is too low as 1 MPa, the glass fragments cannot be prevented from floating when the edge of the cover glass cracks.

Although the embodiment of the present invention has been described above, the embodiment is not limited to the content of this embodiment. The components described above should include those that can be easily conceived by a person skilled in the art, those that are substantially the same, and those within a so-called equivalent range. Further, the components described above can be appropriately combined. Further, various omissions, substitutions, or modifications of the components can be made without departing from the gist of the embodiment described above.

### REFERENCE SIGNS LIST

10 display device
12 cover glass
12A first main surface
12B second main surface
12C end surface
14 display panel
18 frame
20 first adhesive layer
22 second adhesive layer

1. A display device, comprising:
a display panel;
a frame including a portion provided outside the display panel;
a cover glass including a first main surface and a second main surface, the cover glass being provided on or above the display panel and the frame such that the second main surface faces the display panel and the frame; and
a first adhesive layer provided between the second main surface of the cover glass and the frame, the first adhesive layer adhering the second main surface of the cover glass and the frame to each other, wherein
the first adhesive layer has an elastic modulus of 5 MPa or more and 400 MPa or less in an indentation elastic modulus test.

2. The display device according to claim 1, wherein
the cover glass is a chemically strengthened glass having a depth of compressive stress layer being 10 μm or more, has a thickness of 0.3 mm or more and 2.5 mm or less, and has a tensile stress of 5 MPa or more.

3. The display device according to claim 1, wherein
the first adhesive layer has a thickness of 0.2 mm or more and 4.0 mm or less.

4. The display device according to claim 1, having a ratio of an area of the first adhesive layer to an area of the second main surface of the cover glass being 5% or more and 65% or less.

5. The display device according to claim 1, having a distance from an end surface of the cover glass to an end on an outer side of the first adhesive layer being 0 mm or more and 10 mm or less.

6. The display device according to claim 5, having a distance from the end surface of the cover glass to an end on an inner side of the first adhesive layer being 0.5 mm or more and 60 mm or less.

7. The display device according to claim 1, further comprising: a second adhesive layer provided between the second main surface of the cover glass and the display panel, the second adhesive layer adhering the second main surface of the cover glass and the display panel to each other, wherein
the second adhesive layer is formed of an adhesive having a composition different from that of the first adhesive layer.

8. The display device according to claim 7, wherein
the second adhesive layer has an elastic modulus in the indentation elastic modulus test being lower than the elastic modulus of the first adhesive layer in the indentation elastic modulus test.
